(19) United States
(12) Patent Application Publication
(10) Pub. No.: US 2005/0211988 A1
(43) Pub. Date: Sep. 29, 2005

(54) Method for production of a layer of silicon carbide or a nitride of a group III element on a suitable substrate

(75) Inventor: Andre Leycuras, Valbonne (FR)

Correspondence Address: Plevy & Howard, Post Office Box 226, Fort Washington, PA, 19034, US

(73) Assignee: Centre National De La Recherche Scientifique, Paris Cedex 16 (FR)

(21) Appl. No.: 10/504,795

(22) PCT Filed: Feb. 13, 2003
(86) PCT No.: PCT/FR03/00474

§ 371 Date: Apr. 18, 2005

(30) Foreign Application Priority Data
Feb. 15, 2002 (FR) 02/01941

(51) Int. Cl. H01L 29/15

(52) U.S. Cl. 257/77

(57) ABSTRACT

The invention relates to an intermediate product in the production of optical, electronic or opto-electronic components, comprising a crystalline layer of cubic silicon carbide, or of a nitride of an element of group III, such as AlN, InN or GaN on a monocrystalline substrate. The substrate is made from silicon/germanium, the germanium being of an atomic proportion of from 5 to 90% inclusive.

The present invention relates to the forming of optical, electronic, or optoelectronic components.

Optoelectronic components such as lasers, light-emitting diodes, and optical detectors, especially in the ultra-violet, are known to be advantageously able to be formed in cubic or hexagonal crystal layers of group III nitrides, such as aluminum nitride AlN, gallium nitride GaN, indium nitride InN, . . . .

Group III nitrides can in particular be deposited on silicon carbide (SiC)crystals or crystallized layers.

Hexagonal varieties of silicon carbide have been obtained by sublimation growth methods or chemical vapor deposition at very high temperature (2300° C.). However, such very high temperatures and the great susceptibility of the crystal quality to the various heat gradients make them extremely expensive and makes the obtaining of crystals of sufficient size difficult and costly.

Further, it has been attempted to grow cubic silicon carbide layers by chemical vapor deposition on various substrates. Indeed, conversely to the hexagonal varieties for which single-crystal seeds of centimetric dimensions but of very fine quality (spontaneously obtained upon manufacturing of silicon carbide for abrasive purposes) are available to initiate the first growths, no substrate with the mesh parameter of cubic silicon carbide is known. The same problem is posed for group III nitrides, be they cubic or hexagonal.

The most advanced attempts of deposition of a cubic silicon carbide layer have been performed on single-crystal silicon substrates. Indeed, there exists a mesh ratio substantially equal to 5/4 between cubic silicon carbide and a silicon crystal. However, given that silicon carbide epitaxies are performed at temperatures that can reach 1350° C. and that there exists a significant expansion coefficient difference between the silicon carbide layer and the substrate, very strong stress appears upon cooling down.

This stress depends on the thickness of the layer, on that of the substrate, and on the elastic constants of both the layer and the substrate. The thickness values of silicon carbide layers are given as an example in all the text in the case of a substrate with a 300-μm thickness and a 50-mm diameter.

For example, if a 2-μm cubic SiC layer has been formed on a silicon substrate oriented along the (111) plane, a substrate curvature exhibiting a deflection on the order of 0.5 mm can be observed. This phenomenon is enhanced if a thicker silicon carbide layer is desired to be obtained, and this often results in ruptures or cracks of the layer and thus in a very poor final quality of the silicon carbide layer. Further, even if no breakage occurs, the significant obtained curvature prevents from properly carrying out the photolithographic operations necessary in most applications of these layers to the forming of optoelectronic components.

Various attempts have been made to improve this state of things, in particular by using substrates of silicon-on-oxide type, but this has not yielded satisfactory results either. In the case of an SiC growth on a (100) oriented silicon substrate of 300-μm thickness, it is possible to achieve a thickness of 10 μm or more with a curvature, but with no cracks. This enables using the method of PCT patent WO0031317 of the CNRS, invented by André Leycuras, and which consists of converting the substrate silicon into silicon carbide, which suppresses the stress.

The present invention aims at providing the forming of a silicon carbide layer on a substrate enabling obtaining this layer with a sufficient crystal quality without strong mechanical stress.

Another object of the present invention is to provide the forming of such a silicon carbide layer adapted to a subsequent deposition of a group III nitride.

Another object of the present invention is to provide the forming of a layer of a group III nitride on a substrate enabling obtaining this layer with a sufficient crystal quality and exhibiting no strong mechanical stress.

To achieve these objects, the present invention provides using as a substrate a single-crystal silicon-germanium alloy substrate, Si₁₋ₓGeₓ, the germanium proportion, x, ranging from 5 to 90%, from 5 to 20% for silicon carbide, and from 10 to 90% for nitrides.

If the germanium proportion is close to 7% of germanium atoms for 92.5% of silicon atoms, the condition of a ratio of five silicon carbide meshes for four silicon-germanium meshes is substantially perfectly fulfilled, that is, an outstanding single-crystal growth of the silicon carbide on the silicon-germanium can be obtained. However, there then exists a slight expansion coefficient mismatch and a slight curvature of the resulting structure is obtained after cooling down. This curvature remains quite acceptable and causes no remarkable defect when the silicon carbide layer is relatively thin, for example, of a thickness smaller than 5 μm and preferably on the order of from 2 to 3 μm if the substrate orientation is in a (111) plane and up to 20 μm in the case of a (100) orientation.

If the germanium proportion is close to 16% of germanium atoms for 84% of silicon atoms, substantially identical expansion coefficient variations are obtained between temperatures on the order of 1350° C. and the ambient temperature for the silicon carbide and the silicon-germanium. It will thus be preferred to approach this proportion when relatively thick silicon carbide layers, for example, of a thickness of the order of 20 μm, are desired to be grown whatever the orientation of the silicon-germanium substrate. It should be noted that, in this case, the 4-to-5 ratio between meshes is not perfectly satisfied since, given the cubic nature of the obtained silicon carbide, the crystal quality improves as the thickness of the silicon carbide layer obtained by growth increases due to the relatively high probability for extended crystal defects (dislocations and stacking faults) which are not parallel to the growth direction, to annihilate when they cross. A much smaller defect density can thus be observed at the layer surface than at its interface with the substrate in the case of cubic crystals.

What has just been discussed for silicon carbide also applies for the direct growth of a layer of a group III nitride on a silicon-germanium substrate. The substrate composition will then be adapted to optimize the matching of the expansion coefficients or the relation of 5 nitride meshes for 4 SiGe meshes. For example, for GaN, the expansion coefficient matching is optimal for an atomic proportion of 13% of Ge and 87% of Si. However, it will often be preferred to grow a group III nitride on a cubic silicon carbide layer. The (111) orientation of the substrate will be favorable to the growth of the hexagonal form, while the (100) orientation will be favorable to the growth of the cubic form of the nitride layer. The stress in the layer being next to nothing, it is possible to deposit a very thick layer whatever the substrate orientation without for said layer to exhibit cracks. For a 5/4 epitaxial relation, a composition close to 86% of germanium atoms or ranging between 80 and 90% is required. The matching of the expansion coefficients of the layer and of the substrate is not fulfilled, but since the layer is slightly compressed at the ambient temperature, this composition may be advantageous.

A direct application of known growth processes of a silicon carbide layer on silicon does not provide satisfactory silicon carbide layers on a silicon-germanium substrate. Especially, it could be thought that serious problems might arise due to the fact that germanium melts at a temperature on the order of 941° C., and especially because there exists no germanium carbide, which might prevent the forming of a continuous single-crystal SiC layer over the entire substrate surface. Thus, if the methods known for a growth on silicon are applied for a growth on silicon-germanium, and especially if known initial carburization conditions are used, a strongly polycrystalline silicon carbide layer is obtained, and a surface segregation of germanium may form, which can disturb the growth of the SiC layer.

Thus, the present invention, according to one of its aspects, provides the initial forming on a first surface of a silicon-germanium substrate of a very thin layer on the order of from 2 to 10 nm of SiC by carburization by regularly raising the temperature by on the order of 10° C. per second between 800° C. and 1150° C. only. The carburization gas, selected from among usual carburization gases, preferably is propane, in the presence of hydrogen. The obtained layer then appears to have a satisfactory structure while, if a growth in such a temperature range had been carried out on silicon, the deposition would not be performed in single-crystal fashion. Indeed, on silicon, to obtain satisfactory silicon carbide depositions, it must be risen up to a temperature on the order of 1200° C. The above temperature values are given as an example in the case of the reactor formed according to PCT/FR patent application 9902909, invented by André Leycuras. In other reactors, the values may be substantially different, especially due to a different thermal environment of the substrate. There nonetheless remains that, in a given reactor, the carburization of the silicon-germanium alloy is performed at a temperature much smaller than that which should be used for silicon.

Another approach to avoid the problem likely to be posed by the presence of germanium consists of forming by epitaxy or transferring a thin silicon layer, of a thickness from 10 to 50 nm, on the germanium-silicon substrate to be able to return to the known conditions of growth of silicon carbide on silicon.

In a next phase, an epitaxial growth of SiC by chemical vapor deposition is performed and followed by a thickening of the layer by a method of liquid phase conversion of the substrate silicon into silicon carbide, as described for example in PCT patent of the CNRS WO0031317, invented by André Leycuras. This second growth enables reaching SiC thicknesses up to and beyond 20 μm.

As indicated previously, group III nitrides may also be grown directly on silicon-germanium. With a growth of an AlN or GaAlN layer on an SiGe substrate of proper composition, layers may be grown up to a 10-μm thickness and more with no stress and thus with no deformation. It is always advantageous to introduce an AlN/GaN or AlGaN super lattice to filter the dislocations while taking into account the thermal expansion of the general structure to determine the composition of the SiGe substrate which will have the same expansion to null out any thermal stress.

On a carbide or nitride layer obtained according to the present invention, a so-called lateral growth technique may advantageously be applied to the growth of cubic silicon carbide layers or of layers of group III nitrides, especially in particularly advantageous variations using a substrate etch. This operation is much easier in the case of the silicon-germanium alloy than in the case of a growth on a silicon substrate. Further, the absence of stress in the layers enables repeating several times the operations to eliminate, as much as possible, the areas exhibiting defects.

According to an embodiment of the present invention, the silicon carbide layer has a thickness on the order of from 2 to 3 μm, and the germanium is in an atomic proportion close to 7.5%, between 5 and 10%.

According to an embodiment of the present invention, the silicon carbide layer has a thickness on the order of from 5 to 20 μm, and the germanium is in an atomic proportion close to 16%, between 14 and 18%.

According to an embodiment of the present invention, the nitride layer has a thickness on the order of from 1 to 5 μm, and the germanium is in an atomic proportion close to 85%, between 80 and 90%.

According to an embodiment of the present invention, the nitride layer has a thickness on the order of from 5 to 20 μm, and the germanium is in an atomic proportion close to 13%, between 10 and 15%.

According to an embodiment of the present invention, the forming of the silicon carbide layer comprises a first step consisting of carburizing the substrate surface in the presence of a carburization gas selected from the group comprising propane and ethylene, and in the presence of hydrogen, at a temperature smaller than 1150° C. and a second chemical vapor deposition growth step.

According to an embodiment of the present invention, the forming of the silicon carbide layer further comprises a step of growth of a silicon layer of a thickness from 10 to 50 μm before the carburization step.

1. An intermediary product for the forming of optical, electronic, or optoelectronic components, comprising a crystalline cubic silicon carbide layer on a single-crystal substrate, characterized in that the substrate is silicon-germanium, the germanium being in an atomic proportion ranging between 5 and 20%.

2. The product of claim 1, wherein the silicon carbide layer has a thickness of about 2 to 3 μm, and wherein the germanium is in an atomic proportion close to 7.5%, between 5 and 10%.

3. The product of claim 1, wherein the silicon carbide layer has a thickness of about 5 to 20 μm, and wherein the germanium is in an atomic proportion close to 16%, between 14 and 18%.

4. The product of claim 1 or 2, wherein the silicon carbide layer is coated with a nitride group III element.

5. An intermediary product for the forming of optical, electronic, or optoelectronic components, comprising a crystal layer of a group III nitride such as AlN, InN, GaN on a (111) oriented single-crystal silicon-germanium substrate, the germanium being in an atomic proportion ranging between 10 and 90%.

6. The product of claim 5, wherein the nitride layer has a thickness of about 1 to 5 μm, and wherein the germanium is in an atomic proportion close to 85%, between 80 and 90%.

7. The product of claim 5, wherein the nitride layer has a thickness of about 5 to 20 μm, and the germanium is in an atomic proportion close to 13%, between 10 and 15%.

8. A method for forming a cubic silicon carbide crystal layer, consisting of growing by epitaxy said layer on a single-crystal silicon-germanium substrate, the germanium being in an atomic proportion ranging between 5 and 20%.

9. The method of claim 8, wherein the forming of the silicon carbide layer comprises a first step consisting of carburizing the substrate surface in the presence of a carburization gas selected from the group comprising propane and ethylene, and in the presence of hydrogen, at a temperature smaller than 1150° C. and a second step of chemical vapor deposition.

10. The method of claim 9, further comprising a step of growth of a silicon layer of a thickness of 10 to 50 μm before the carburization step.

11. The method of claim 9, further comprising a step of liquid phase conversion of the silicon into silicon carbide.

12. The method of claim 8, further consisting of growing a layer of a group III nitride on the silicon carbide layer.

13. A method for forming a crystal layer of a nitride of group III element, consisting of growing said layer on a single-crystal silicon-germanium substrate, the germanium being in an atomic proportion ranging between 10 and 90%.
